(19) United States
(12) Patent Application Publication
(10) Pub. No.: US 2019/0164893 A1
(43) Pub. Date: May 30, 2019

(54) SEMICONDUCTOR PACKAGE

(71) Applicant: Samsung Electro-Mechanics, Co., Ltd., Suwon-si (KR)

(72) Inventors: Han KIM, Suwon-si (KR); Eun Jung JO, Suwon-si (KR); Jung Ho SHIM, Suwon-si (KR)

(21) Appl. No.: 15/940,104

(22) Filed: Mar. 29, 2018

(30) Foreign Application Priority Data
Nov. 30, 2017 (KR) 10-2017-0162706

(51) Int. Cl. H01L 23/538; H01L 23/498; H01L 23/367; H01L 23/31; H01L 25/10

(52) U.S. Cl. CPC H01L 23/5386; H01L 23/5389; H01L 23/49822; H01L 23/49827; H01L 2225/1058; H01L 23/49816; H01L 23/3128; H01L 25/105; H01L 23/367

(57) ABSTRACT

A semiconductor package includes: an interposer having a first surface and a second surface and including a first redistribution layer; a semiconductor chip having an active surface having connection electrodes disposed thereon and an inactive surface and disposed on the interposer so that the inactive surface faces the second surface of the interposer; an encapsulant disposed on the second surface of the interposer, including a photosensitive insulating material, and having a first region covering the semiconductor chip and a second region positioned around the semiconductor chip; and a second redistribution layer including second vias penetrating through the first region of the encapsulant and connected to the connection electrodes, through-vias penetrating through the second region of the encapsulant and connected to the first redistribution layer, and second wiring patterns disposed on the encapsulant and having integrated structures with the second vias and the through-vias.

### CROSS-REFERENCE TO RELATED APPLICATION(S)

This application is based on and claims the benefit of priority to Korean Patent Application No. 10-2017-0162706 filed on Nov. 30, 2017 in the Korean Intellectual Property Office, the entire disclosure of which is incorporated herein by reference.

### TECHNICAL FIELD

The present disclosure relates to a semiconductor package, and more particularly, to a fan-out semiconductor package for a package-on-package (POP) structure.

### BACKGROUND

Recently, a significant trend in the development of technologies related to semiconductor packaging is reducing the overall size of semiconductor packages while maintaining performance of the product. As an example, in fan-out semiconductor packaging, connection terminals may be redistributed to outside of a mounting region of a semiconductor chip, such that the connection terminals may be efficiently arranged and fan-out semiconductor packages may be maintained at a small size.

In a package-on-package (POP) structure that has been recently developed, many connection terminals (for example, I/Os) of an upper package and a lower package need to be connected to each other, and a connection member such as an interposer is required in order to connect the connection terminals to each other.

### SUMMARY

An aspect of the present disclosure may provide a semiconductor package of which an increase in a thickness due to introduction of a connection member, such as an interposer, may be suppressed.

According to an aspect of the present disclosure, a semiconductor package may be provided, in which a process and a structure are simplified by using a connection member manufactured in advance as an interposer and a connection structure between redistribution layers of connection members disposed on and beneath a semiconductor chip is improved.

According to an aspect of the present disclosure, a semiconductor package may include: an interposer having a first surface and a second surface opposing each other and including a first redistribution layer having a plurality of first wiring patterns and first vias connected to the plurality of first wiring patterns; a semiconductor chip having an active surface having connection electrodes disposed thereon and an inactive surface opposing the active surface and disposed on the interposer so that the inactive surface faces the second surface of the interposer; an encapsulant disposed on the second surface of the interposer, including a photosensitive insulating material, and having a first region covering the active surface of the semiconductor chip and a second region positioned in the vicinity of the semiconductor chip; and a second redistribution layer including second vias penetrating through the first region of the encapsulant and connected to the connection electrodes, through-vias penetrating through the second region of the encapsulant and connected to the first redistribution layer, and second wiring patterns disposed on the encapsulant and having integrated structures with the second vias and the through-vias.

According to another aspect of the present disclosure, a semiconductor package may include: an interposer having a first surface having a plurality of pads provided thereon and a second surface opposing the first surface and including a first redistribution layer connected to the plurality of pads; a semiconductor chip having an active surface having connection electrodes disposed thereon and an inactive surface opposing the active surface and disposed on the interposer so that the inactive surface faces the second surface of the interposer; an encapsulant disposed on the second surface of the interposer, including a photosensitive insulating material, and having a first region covering the active surface of the semiconductor chip and a second region positioned in the vicinity of the semiconductor chip; a second redistribution layer including connection vias penetrating through the first region of the encapsulant and connected to the connection electrodes, through-vias penetrating through the second region of the encapsulant and connected to the first redistribution layer, and wiring patterns disposed on the encapsulant and having integrated structures with the connection vias and the through-vias; and a connection member having a first surface disposed on the encapsulant and a second surface opposing the first surface and having electrical connection structures disposed thereon, and including a third redistribution layer connected to the second redistribution layer and the electrical connection structures, wherein the first redistribution layer having a plurality of first wiring patterns and first vias connected to the plurality of first wiring patterns, first wiring patterns adjacent to the first surface of the interposer among the plurality of first wiring patterns protrude from the interposer, and first wiring patterns adjacent to the second surface of the interposer among the plurality of first wiring patterns are embedded in the interposer.

### BRIEF DESCRIPTION OF DRAWINGS

The above and other aspects, features, and advantages of the present disclosure will be more clearly understood from the following detailed description taken in conjunction with the accompanying drawings, in which:

FIG. 1 is a schematic block diagram illustrating an example of an electronic device system;

FIG. 2 is a schematic perspective view illustrating an example of an electronic device;

FIGS. 3A and 3B are schematic cross-sectional views illustrating states of a fan-in semiconductor package before and after being packaged;

FIG. 4 is schematic cross-sectional views illustrating a packaging process of a fan-in semiconductor package;

FIG. 5 is a schematic cross-sectional view illustrating a case in which a fan-in semiconductor package is mounted on an interposer substrate and is finally mounted on a main board of an electronic device;

FIG. 6 is a schematic cross-sectional view illustrating a case in which a fan-in semiconductor package is embedded in an interposer substrate and is finally mounted on a main board of an electronic device;

FIG. 7 is a schematic cross-sectional view illustrating a fan-out semiconductor package;

FIG. 8 is a schematic cross-sectional view illustrating a case in which a fan-out semiconductor package is mounted on a main board of an electronic device;

FIG. 9 is a side cross-sectional view illustrating a semiconductor package according to an exemplary embodiment in the present disclosure;

FIGS. 10A and 10B are, respectively, a plan view and a bottom view illustrating the semiconductor package illustrated in FIG. 9;

FIG. 11 is an enlarged view of part “A” of the semiconductor package illustrated in FIG. 9;

FIG. 12 is a side cross-sectional view illustrating a package-on-package (POP) structure including the semiconductor package illustrated in FIG. 9;

FIGS. 13A through 13F are cross-sectional views illustrating main processes of a method of manufacturing the semiconductor package illustrated in FIG. 9;

FIG. 14 is a side cross-sectional view illustrating a semiconductor package according to another exemplary embodiment in the present disclosure; and

FIGS. 15A through 15C are cross-sectional views illustrating main processes of a method of manufacturing the semiconductor package illustrated in FIG. 14.

### DETAILED DESCRIPTION

Hereinafter, exemplary embodiments in the present disclosure will be described with reference to the accompanying drawings. In the accompanying drawings, shapes, sizes, and the like, of components may be exaggerated or shortened for clarity.

The meaning of a “connection” of a component to another component in the description includes an indirect connection through an adhesive layer as well as a direct connection between two components. In addition, “electrically connected” conceptually includes a physical connection and a physical disconnection. It can be understood that when an element is referred to with terms such as “first” and “second”, the element is not limited thereby. They may be used only for a purpose of distinguishing the element from the other elements, and may not limit the sequence or importance of the elements. In some cases, a first element may be referred to as a second element without departing from the scope of the claims set forth herein. Similarly, a second element may also be referred to as a first element.

The term an “exemplary embodiment” used herein does not refer to the same exemplary embodiment, and is provided to emphasize a particular feature or characteristic different from that of another exemplary embodiment. However, exemplary embodiments provided herein are considered to be able to be implemented by being combined in whole or in part with one another. For example, one element described in a particular exemplary embodiment, even if it is not described in another exemplary embodiment, may be understood as a description related to another exemplary embodiment, unless an opposite or contradictory description is provided therein.

Terms used herein are used only in order to describe an exemplary embodiment rather than limiting the present disclosure. For example, singular forms need to be interpreted as including plural forms unless interpreted otherwise in context.

Electronic Device

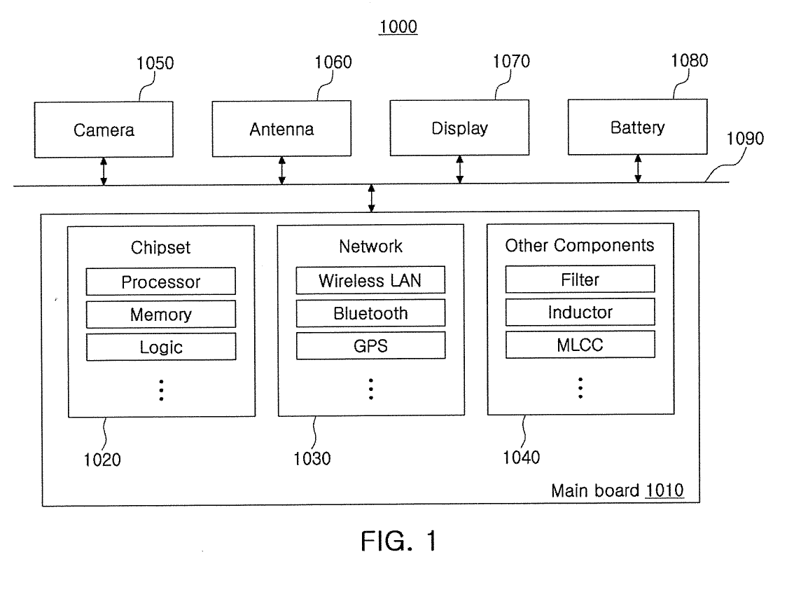

FIG. 1 is a schematic block diagram illustrating an example of an electronic device system.

Referring to FIG. 1, an electronic device 1000 may accommodate a mainboard 1010 therein. The mainboard 1010 may include chip related components 1020, network related components 1030, other components 1040, and the like, physically or electrically connected thereto. These components may be connected to others to be described below to form various signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital converter (ADC), an application-specific integrated circuit (ASIC), or the like. However, the chip related components 1020 are not limited thereto, and may also include other types of chip-related components. In addition, the chip related components 1020 may be combined with each other.

The network related components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+(HSPA+), high speed downlink packet access+(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols, designated after the abovementioned protocols. However, the network related components 1030 are not limited thereto, and may also include a variety of other wireless or wired standards or protocols. In addition, the network related components 1030 may be combined with each other, together with the chip related components 1020 described above.

Other components 1040 may include a high frequency inductor, a ferrite inductor, a power inductor, ferrite beads, a low temperature co-firing ceramic (LTCC), an electromagnetic interference (EMI) filter, a multilayer ceramic capacitor (MLCC), and the like. However, other components 1040 are not limited thereto, and may also include passive components used for various other purposes, and the like. In addition, other components 1040 may be combined with each other, together with the chip related components 1020 or the network related components 1030 described above.

Depending on a type of the electronic device 1000, the electronic device 1000 may include other components that may or may not be physically or electrically connected to the mainboard 1010. These other components may include, for example, a camera 1050, an antenna 1060, a display device 1070, a battery 1080, an audio codec (not illustrated), a video codec (not illustrated), a power amplifier (not illustrated), a compass (not illustrated), an accelerometer (not illustrated), a gyroscope (not illustrated), a speaker (not illustrated), a mass storage unit (for example, a hard disk drive) (not illustrated), a compact disk (CD) drive (not illustrated), a digital versatile disk (DVD) drive (not illustrated), or the like. However, these other components are not limited thereto, and may also include other components used for various purposes depending on a type of electronic device 1000, or the like.

The electronic device 1000 may be a smartphone, a personal digital assistant (PDA), a digital video camera, a digital still camera, a network system, a computer, a monitor, a tablet personal computer (PC), a laptop PC, a netbook PC, a television, a video game machine, a smartwatch, an automotive component, or the like. However, the electronic device 1000 is not limited thereto, and may be any other electronic device processing data.

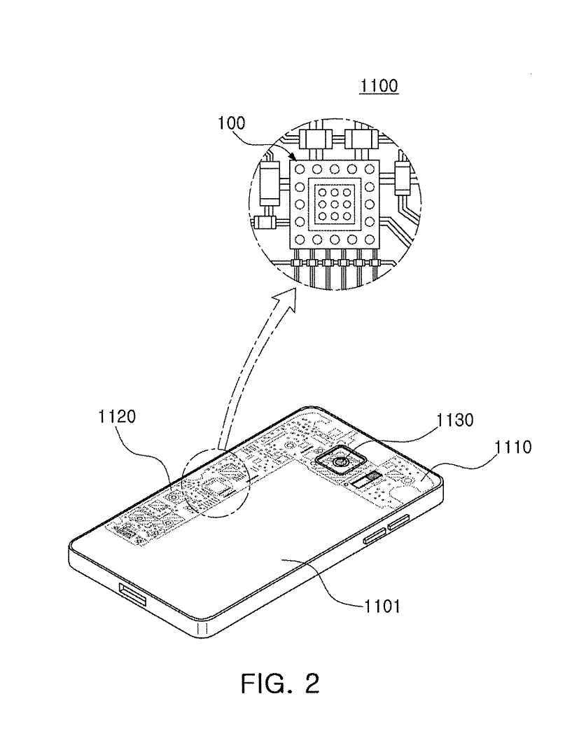

FIG. 2 is a schematic perspective view illustrating an example of an electronic device.

Referring to FIG. 2, a semiconductor package may be used for various purposes in the various electronic devices 1000 as described above. For example, a motherboard 1110 may be accommodated in a body 1101 of a smartphone 1100, and various components 1120 may be physically or electrically connected to the motherboard 1110. In addition, other components that may or may not be physically or electrically connected to the mainboard 1010, such as a camera 1130, may be accommodated in the body 1101. Some of the electronic components 1120 may be the chip related components, and the semiconductor package 100 may be, for example, an application processor among the chip related components, but is not limited thereto. The electronic device is not necessarily limited to the smartphone 1100, and may be other electronic devices as described above.

Semiconductor Package

Generally, numerous fine electrical circuits are integrated in a semiconductor chip. However, the semiconductor chip may not serve as a finished semiconductor product in itself, and may be damaged due to external physical or chemical impacts. Therefore, the semiconductor chip itself may not be used, and may be packaged and used in an electronic device, or the like, in a packaged state.

Here, semiconductor packaging is required, due to the existence of a difference in a circuit width between the semiconductor chip and a mainboard of the electronic device in terms of electrical connections. In detail, a size of connection pads of the semiconductor chip and an interval between the connection pads of the semiconductor chip are very fine, but a size of component mounting pads of the mainboard used in the electronic device and an interval between the component mounting pads of the mainboard are significantly larger than those of the semiconductor chip. Therefore, it may be difficult to directly mount the semiconductor chip on the mainboard, and packaging technology for buffering a difference in a circuit width between the semiconductor chip and the mainboard is required.

A semiconductor package manufactured by the packaging technology may be classified as a fan-in semiconductor package or a fan-out semiconductor package depending on a structure and a purpose thereof.

The fan-in semiconductor package and the fan-out semiconductor package will hereinafter be described in more detail with reference to the drawings.

Fan-in Semiconductor Package

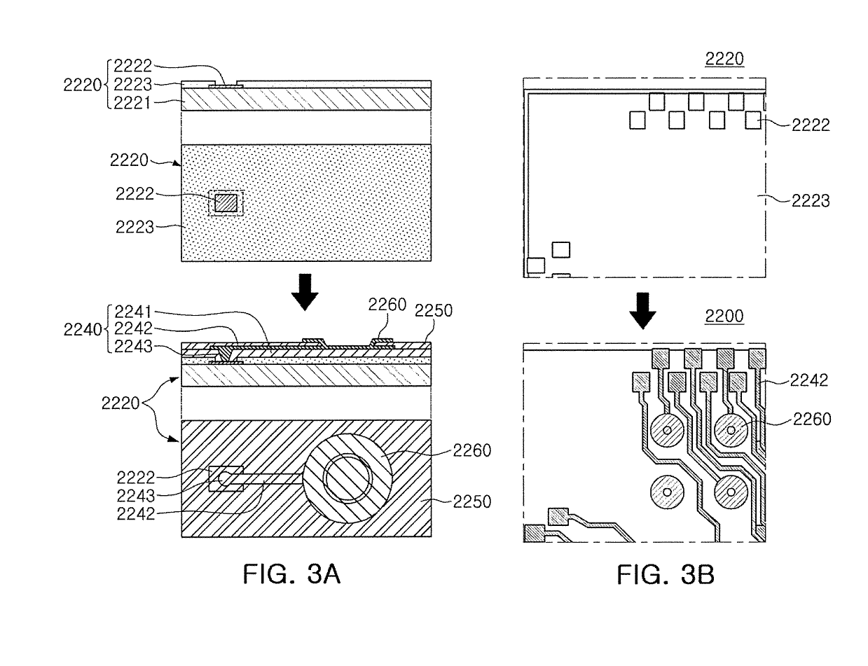

FIGS. 3A and 3B are schematic cross-sectional views illustrating states of a fan-in semiconductor package before and after being packaged.

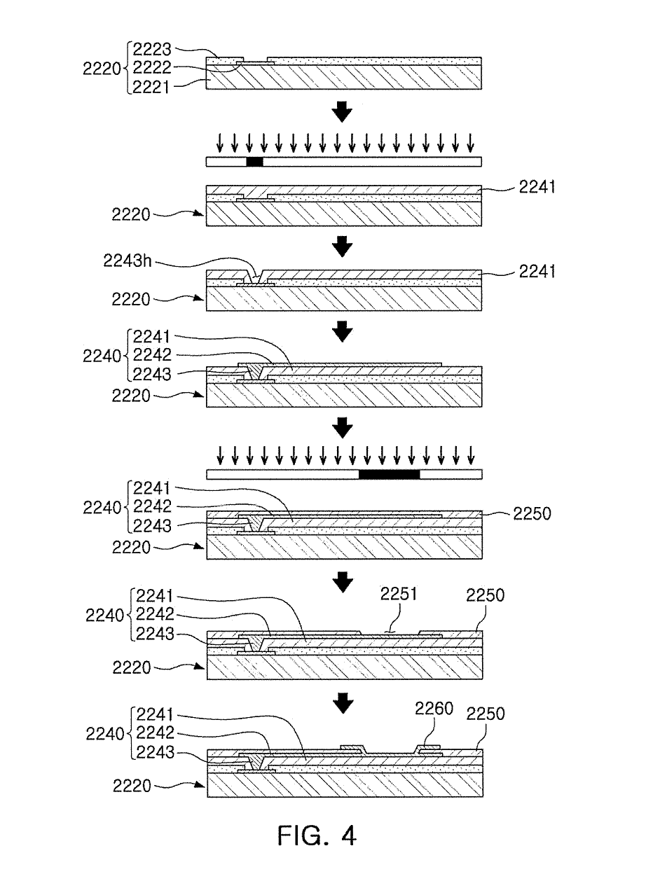

FIG. 4 is a schematic cross-sectional view illustrating a packaging process of a fan-in semiconductor package.

Referring to the drawings, a semiconductor chip 2220 may be, for example, an integrated circuit (IC) in a bare state, including a body 2221 including silicon (Si), germanium (Ge), gallium arsenide (GaAs), or the like, connection pads 2222 formed on one surface of the body 2221 and including a conductive material such as aluminum (Al), or the like, and a passivation layer 2223 such as an oxide film, a nitride film, or the like, formed on one surface of the body 2221 and covering at least portions of the connection pads 2222. In this case, since the connection pads 2222 may be significantly small, it may be difficult to mount the integrated circuit (IC) on an intermediate level printed circuit board (PCB) as well as on the mainboard of the electronic device, or the like.

Therefore, depending on a size of the semiconductor chip 2220, a connection member 2240 may be formed on the semiconductor chip 2220 in order to redistribute the connection pads 2222. The connection member 2240 may be formed by forming an insulating layer 2241 on the semiconductor chip 2220 using an insulating material such as photoimagable dielectric (PID) resin, forming via holes 2243h opening the connection pads 2222, and then forming wiring patterns 2242 and vias 2243. Then, a passivation layer 2250 protecting the connection member 2240 may be formed, an opening 2251 may be formed, and an underbump metal layer 2260, or the like, may be formed. That is, a fan-in semiconductor package 2200 including, for example, the semiconductor chip 2220, the connection member 2240, the passivation layer 2250, and the under-bump metal layer 2260 may be manufactured through a series of processes.

As described above, the fan-in semiconductor package may have a package form in which all of the connection pads, for example, input/output (I/O) terminals, of the semiconductor chip, are disposed inside the semiconductor chip, and may have excellent electrical characteristics and be produced at a low cost. Therefore, many elements mounted in smartphones have been manufactured in a fan-in semiconductor package form. In detail, many elements mounted in smartphones have been developed to implement a rapid signal transfer while having a compact size.

However, since all I/O terminals need to be disposed inside the semiconductor chip in the fan-in semiconductor package, the fan-in semiconductor package has significant spatial limitations. Therefore, it is difficult to apply this structure to a semiconductor chip having a large number of I/O terminals or a semiconductor chip having a compact size. In addition, due to the disadvantage described above, the fan-in semiconductor package may not be directly mounted and used on the mainboard of the electronic device. The reason is that even in a case in which a size of the I/O terminals of the semiconductor chip and an interval between the I/O terminals of the semiconductor chip are increased by a redistribution process, the size of the I/O terminals of the semiconductor chip and the interval between the I/O terminals of the semiconductor chip may not be sufficient to directly mount the fan-in semiconductor package on the mainboard of the electronic device.

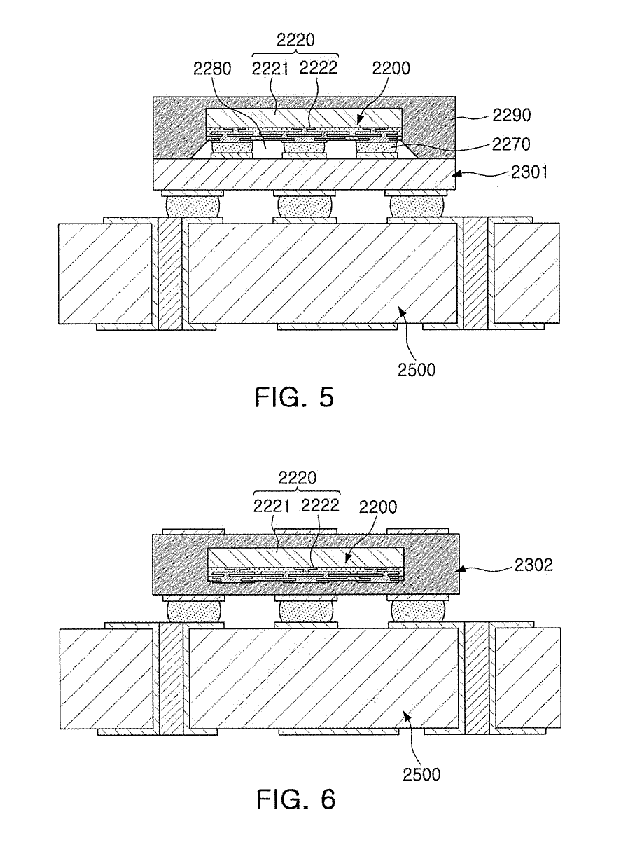

FIG. 5 is a schematic cross-sectional view illustrating a case in which a fan-in semiconductor package is mounted on an interposer substrate and is ultimately mounted on a mainboard of an electronic device.

FIG. 6 is a schematic cross-sectional view illustrating a case in which a fan-in semiconductor package is embedded in an interposer substrate and is ultimately mounted on a mainboard of an electronic device.

Referring to FIGS. 5 and 6, in a fan-in semiconductor package 2200, connection pads 2222, that is, I/O terminals, of a semiconductor chip 2220 may be redistributed through an interposer substrate 2301, and the fan-in semiconductor package 2200 may be ultimately mounted on a mainboard 2500 of an electronic device in a state in which it is mounted on the interposer substrate 2301. In this case, solder balls 2270, and the like, may be fixed by an underfill resin 2280, or the like, and an outer side of the semiconductor chip 2220 may be covered with a molding material 2290, or the like. Alternatively, a fan-in semiconductor package 2200 may be embedded in a separate interposer substrate 2302, connection pads 2222, that is, I/O terminals, of the semiconductor chip 2220 may be redistributed by the interposer substrate 2302 in a state in which the fan-in semiconductor package 2200 is embedded in the interposer substrate 2302, and the fan-in semiconductor package 2200 may be ultimately mounted on a mainboard 2500 of an electronic device.

As described above, it may be difficult to directly mount and use the fan-in semiconductor package on the mainboard of the electronic device. Therefore, the fan-in semiconductor package may be mounted on the separate interposer substrate and be then mounted on the mainboard of the electronic device through a packaging process or may be mounted and used on the mainboard of the electronic device in a state in which it is embedded in the interposer substrate.

Fan-Out Semiconductor Package

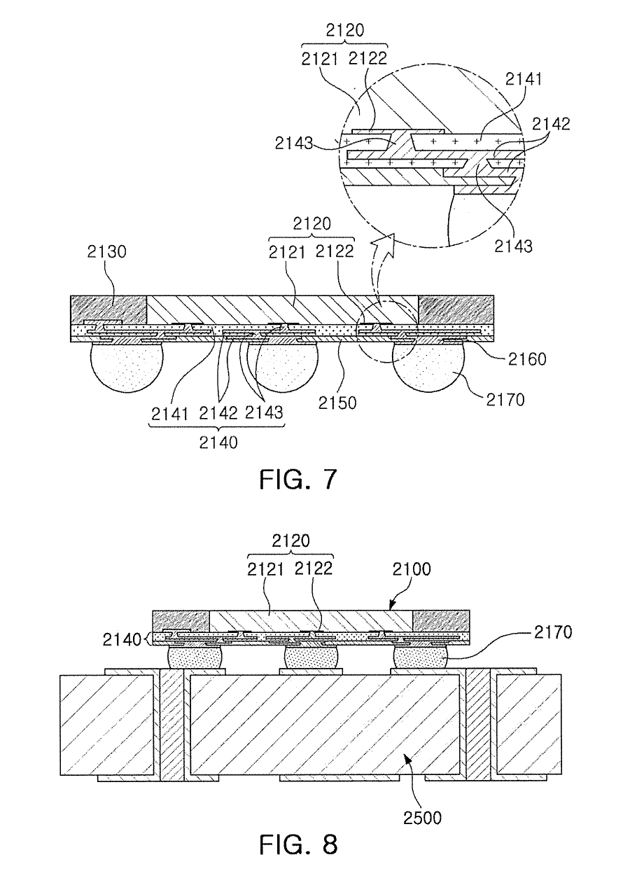

FIG. 7 is a schematic cross-sectional view illustrating a fan-out semiconductor package.

Referring to FIG. 7, in a fan-out semiconductor package 2100, for example, an outer side of a semiconductor chip 2120 may be protected by an encapsulant 2130, and connection pads 2122 of the semiconductor chip 2120 may be redistributed outwardly of the semiconductor chip 2120 by a connection member 2140. In this case, a passivation layer 2150 may further be formed on the connection member 2140, and an underbump metal layer 2160 may further be formed in openings of the passivation layer 2150. Solder balls 2170 may further be formed on the underbump metal layer 2160. The semiconductor chip 2120 may be an integrated circuit (IC) including a body 2121, the connection pads 2122, a passivation layer (not illustrated), and the like. The connection member 2140 may include an insulating layer 2141, redistribution layers 2142 formed on the insulating layer 2141, and vias 2143 electrically connecting the connection pads 2122 and the redistribution layers 2142 to each other.

As described above, the fan-out semiconductor package may have a form in which I/O terminals of the semiconductor chip are redistributed and disposed outwardly of the semiconductor chip through the connection member formed on the semiconductor chip. As described above, in the fan-in semiconductor package, all I/O terminals of the semiconductor chip need to be disposed inside the semiconductor chip. Therefore, when a size of the semiconductor chip is decreased, a size and a pitch of balls need to be decreased, such that a standardized ball layout may not be used in the fan-in semiconductor package. On the other hand, the fan-out semiconductor package has the form in which the I/O terminals of the semiconductor chip are redistributed and disposed outwardly of the semiconductor chip through the connection member formed on the semiconductor chip as described above. Therefore, even in a case in which a size of the semiconductor chip is decreased, a standardized ball layout may be used in the fan-out semiconductor package as it is, such that the fan-out semiconductor package may be mounted on the mainboard of the electronic device without using a separate interposer substrate, as described below.

FIG. 8 is a schematic cross-sectional view illustrating a case in which a fan-out semiconductor package is mounted on a mainboard of an electronic device.

Referring to FIG. 8, a fan-out semiconductor package 2100 may be mounted on a mainboard 2500 of an electronic device through solder balls 2170, or the like. That is, as described above, the fan-out semiconductor package 2100 includes the connection member 2140 formed on the semiconductor chip 2120 and capable of redistributing the connection pads 2122 to a fan-out region that is outside of a size of the semiconductor chip 2120, such that the standardized ball layout may be used in the fan-out semiconductor package 2100 as it is. As a result, the fan-out semiconductor package 2100 may be mounted on the mainboard 2500 of the electronic device without using a separate interposer substrate, or the like.

As described above, since the fan-out semiconductor package may be mounted on the mainboard of the electronic device without using the separate interposer substrate, the fan-out semiconductor package may be implemented at a thickness lower than that of the fan-in semiconductor package using the interposer substrate. Therefore, the fan-out semiconductor package may be miniaturized and thinned. In addition, the fan-out semiconductor package has excellent thermal characteristics and electrical characteristics, such that it is particularly appropriate for a mobile product. Therefore, the fan-out semiconductor package may be implemented in a form more compact than that of a general package-on-package (POP) type using a printed circuit board (PCB), and may solve a problem due to the occurrence of a warpage phenomenon.

Meanwhile, the fan-out semiconductor package refers to package technology for mounting the semiconductor chip on the mainboard of the electronic device, or the like, as described above, and protecting the semiconductor chip from external impacts, and is a concept different from that of a printed circuit board (PCB) such as an interposer substrate, or the like, having a scale, a purpose, and the like, different from those of the fan-out semiconductor package, and having the fan-in semiconductor package embedded therein.

A semiconductor package that uses a connection member such as an interposer manufactured in advance will hereinafter be described in detail with reference to the accompanying drawings.

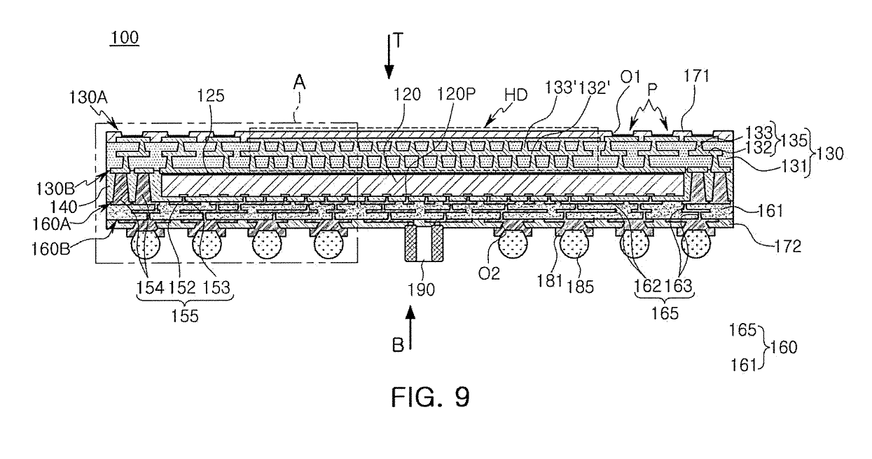

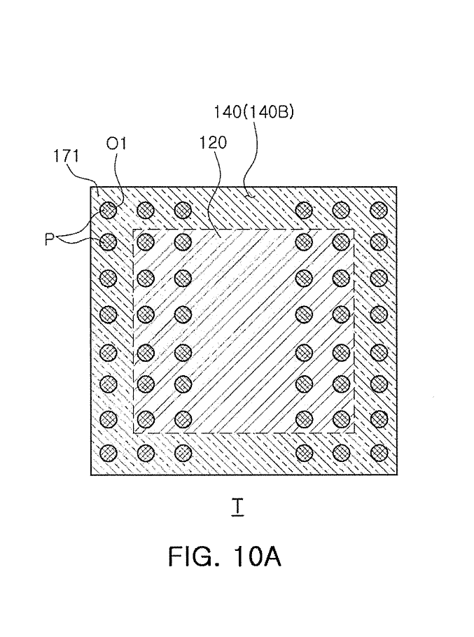

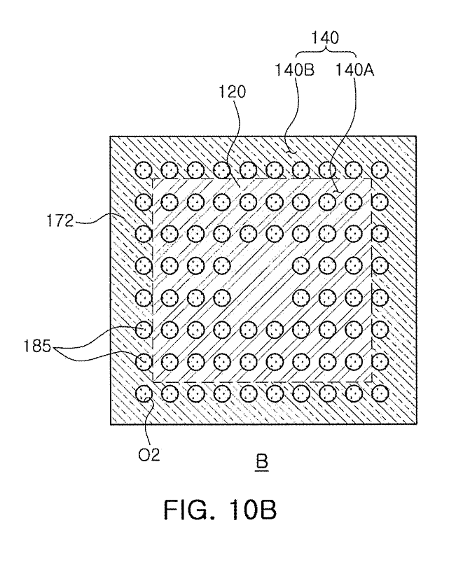

FIG. 9 is a side cross-sectional view illustrating a semiconductor package according to an exemplary embodiment in the present disclosure. FIGS. 10A and 10B are, respectively, a plan view (viewed from “T” of FIG. 9) and a bottom view (viewed from “B” of FIG. 9) illustrating the semiconductor package illustrated in FIG. 9.

Referring to FIG. 9, a semiconductor package 100 according to the present exemplary embodiment may include an interposer 130 having a first surface 130A and a second surface 130B opposing each other and having a first redistribution layer 135, a semiconductor chip 120 disposed on the second surface 130B of the interposer 130, an encapsulant 140 disposed on the second surface 130B of the interposer 130 and covering the semiconductor chip 120, a second redistribution layer 155 disposed on the encapsulant 140 and connected to the first redistribution layer 135, and a connection member 160 having a first surface 160A disposed on the encapsulant 140 and a second surface 160B opposing the first surface 160A and having a third redistribution layer 165 connected to the second redistribution layer 155.

In the interposer 130 used in the present exemplary embodiment, the first redistribution layer 135 may include a plurality of first wiring patterns 132 and a plurality of first vias 133 connected to the plurality of first wiring patterns 132.

The semiconductor chip 120 may have an active surface having a plurality of connection electrodes 120P disposed thereon and an inactive surface opposing the active surface. The inactive surface of the semiconductor chip 120 and the second surface 130B of the interposer 130 may be bonded to each other using a bonding layer 125.

The second redistribution layer 155 used in the present exemplary embodiment may be directly connected to the connection electrodes 120P of the semiconductor chip 120, and may connect the first redistribution layer 135 of the interposer 130 and the third redistribution layer 165 of the connection member 160 to each other. The encapsulant 140 may be divided into a first region 140A covering the semiconductor chip 120 and a second region 140B positioned in the vicinity of the semiconductor chip 120.

The second redistribution layer 155 may include connection vias (also referred to as ‘second vias’) 153 penetrating through the first region 140A of the encapsulant 140 and connected to the connection electrodes 120P and through-vias 154 penetrating through the second region 140B of the encapsulant 140 and connected to the first redistribution layer 135. In addition, the second redistribution layer 155 may include second wiring patterns 152 disposed on the encapsulant 140 and connected to at least one of the connection vias 153 and the through-vias 154. The third redistribution layer 165 may be connected to the connection vias 153 and the through-vias 154 through the second wiring patterns 152.

A first passivation layer 171 may be formed on the first surface 130A of the interposer 130. The first passivation layer 171 may have first openings O1 defining regions of a plurality of pads P. The first openings O1 may be formed to correspond to an array of connection terminals of another semiconductor chip and package to be disposed on the semiconductor package. The plurality of pads P may be formed using a metal such as Au, and be provided as pads for connection to another package and chip.

Electrical connection structures 185 connected to the third redistribution layer 165 may be disposed on the second surface 160B of the connection member 160. The electrical connection structures 185 may be connected to the third redistribution layer 165 through an underbump metallurgy (UBM) layer 181. A second passivation layer 172 may be disposed on the second surface 160B of the connection member 160. The second passivation layer 172 may have second openings O2 defining regions of the third redistribution layer 165 connected to the UBM layer 181.

In the present exemplary embodiment, as illustrated in FIG. 10A, the plurality of pads P may have pads disposed in an 8×3 array on each of both sides of the semiconductor package 100. As illustrated in FIG. 10B, the electrical connection structures 185 is illustrated in a 10×10 array, except for a central region (4×4). The plurality of pads P and the electrical connection structures 185 may be divided into fan-in pads that overlap the semiconductor chip 120 and fan-out pads that do not overlap the semiconductor chip 120.

The plurality of pads P may have an array corresponding to that of connection terminals of an upper semiconductor package mounted on the semiconductor package 100, and the electrical connection structures 185 may be arrayed to correspond to connection terminals of a mother board on which the semiconductor package 100 is to be disposed. The plurality of pads P and the electrical connection structures 185 may be formed to have various other numbers and be formed in various arrays depending on the upper semiconductor package and the mother board.

As described above, the plurality of pads P and the electrical connection structures 185 may be connected to each other and may also be connected to the semiconductor chip 120 by the first and third redistribution layers 135 and 165 together with the second redistribution layer 155.

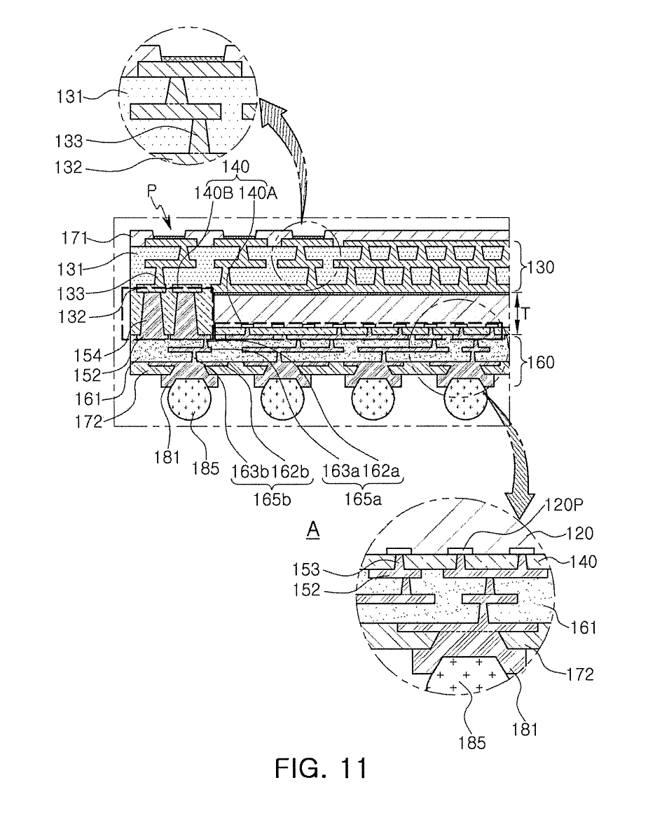

In the present exemplary embodiment, vias and patterns constituting the first and third redistribution layers 135 and 165 and the second redistribution layer 155 may have characteristic structures by a unique process. FIG. 11 is an enlarged view of part “A” of the semiconductor package illustrated in FIG. 9.

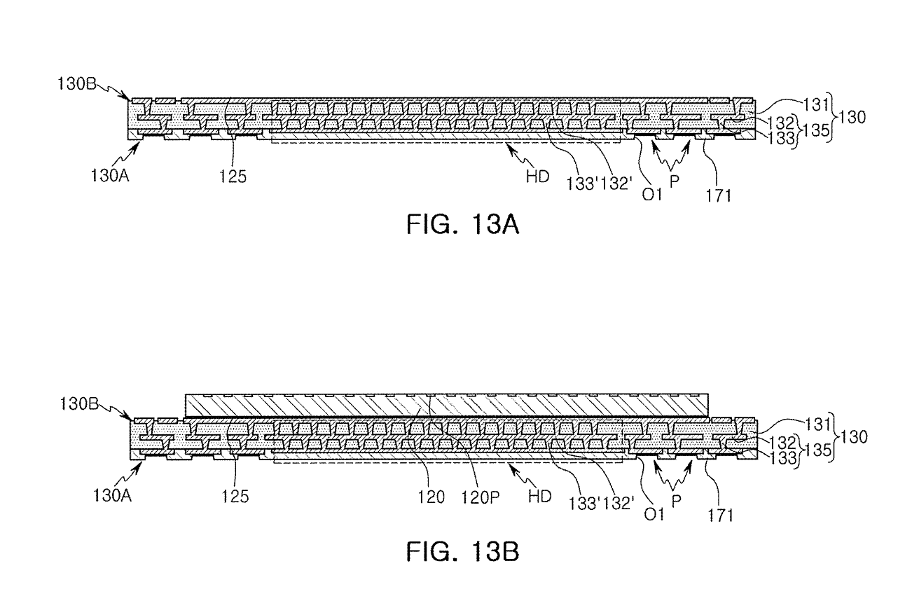

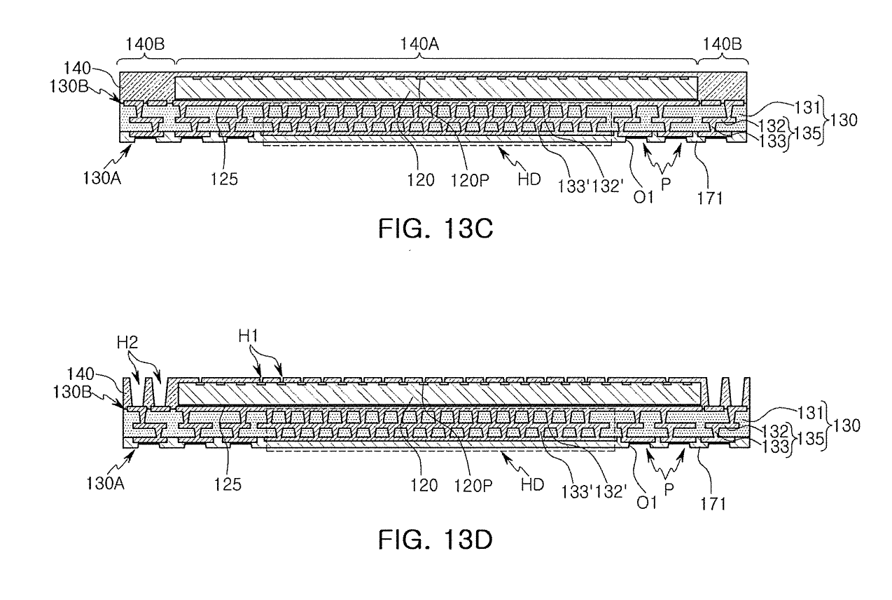

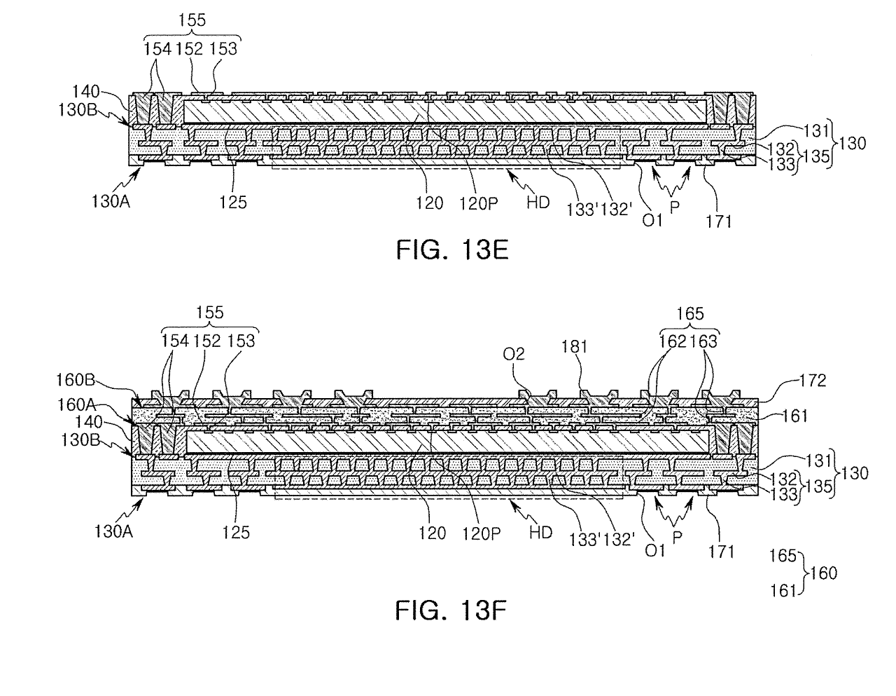

Referring to FIG. 11, the second wiring patterns 152 may have integrated structures with the connection vias 153 and the through-vias 154. In the present specification, a term “integrated structure” does not mean that two components are simply in contact with each other, but refers to a structure in which two components are formed integrally with each other using the same material by the same process. For example, the second wiring patterns 152 may be considered to have the “integrated structure” with the connection vias 153 and the through-vias 154 since they are formed simultaneously with the connection vias 153 and the through-vias 154 by the same plating process (see a process of FIG. 13E). As described above, the connection vias 153 and the through-vias 154 may be formed of the same metal. In addition, the connection vias 153 and the through-vias 154 may have integrated structures with the second wiring patterns 152.

The encapsulant 140 may be formed of a photosensitive material. As described above, the encapsulant 140 may cover the semiconductor chip 120 disposed on the second surface 160B of the connection member 160, and desired holes may be formed by a precise drilling process for a photoresist in order to form the connection vias 153 and the through-vias 154 for the second redistribution layer 155 (see FIG. 13D).

The holes for the connection vias 153 may be formed from an upper surface of the encapsulant 140 toward the semiconductor chip 120 (see FIG. 13E). Therefore, an area of a surface of the connection via 153 adjacent to the connection member 160 may be greater than that of a surface of the connection via 153 adjacent to the semiconductor chip 120 (see a detailed view ‘A’ of FIG. 11). Likewise, since the holes for the through-vias 154 may be formed from the upper surface of the encapsulant 140 toward the connection member 160, an area of a surface of the through-via 154 adjacent to the connection member 160 may be greater than that of a surface of the through-via 154 adjacent to the interposer 130.

In the connection member 160 used in the present exemplary embodiment, the third redistribution layer 165 may include a plurality of third wiring patterns 162 and a plurality of third vias 163. In detail, the third redistribution layer 165 may include two insulating layers 161, third wiring patterns 162 each disposed on the two insulating layers 161, and third vias 163 each connected to the third wiring patterns 162. The third vias 163 may include vias connecting the second redistribution layer 155 and the third wiring patterns 162 to each other and vias connecting the third wiring patterns 162 to each other. A case in which the third redistribution layer 165 includes two-layer redistribution structures 165a and 165b is illustrated by way of example. However, the third redistribution layer 165 is not limited thereto, but may have single-layer or three-layer or more redistribution structures.

The insulating layer 161 of the third redistribution layer 165 may be formed of a photosensitive insulating material such as a photoimagable dielectric (PID). An area of a surface of the third via 163 of the third redistribution layer 165 adjacent to the first surface 160A of the connection member 160 may be smaller than that of a surface of the third via 163 of the third redistribution layer 165 adjacent to the second surface 160B of the connection member 160.

An area of a surface of the via of the first redistribution layer 135 adjacent to the first surface 130A of the interposer 130 may be smaller than that of a surface of the via of the first redistribution layer 135 adjacent to the second surface 130B of the interposer 130. In the present exemplary embodiment, the interposer 130 is manufactured in advance before the semiconductor chip 120 is mounted, and directions of the vias may thus be reversed, if necessary.

The respective components included in the semiconductor package 100 according to the present exemplary embodiment will hereinafter be described in more detail.

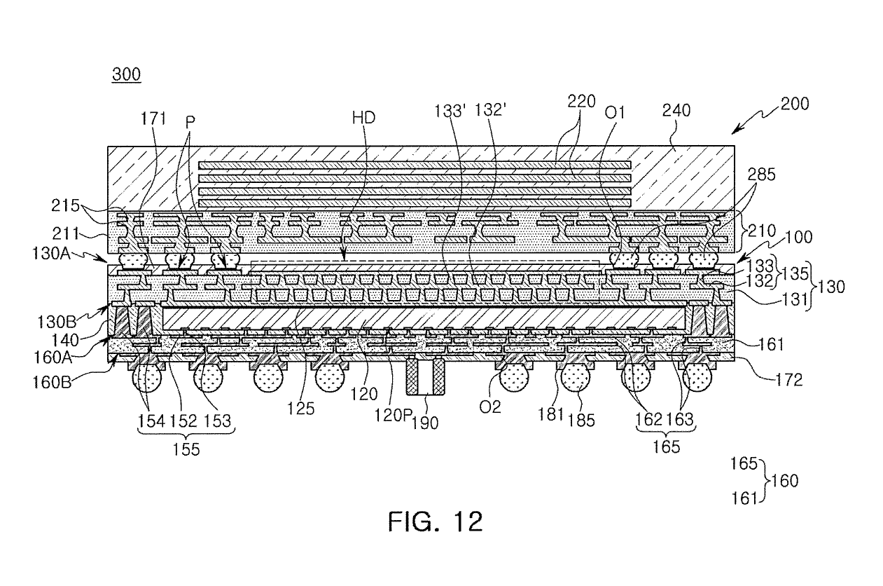

The interposer 130 may be used as an interposer connecting upper and lower packages to each other (see FIG. 12). As described above, the interposer 130 used in the present exemplary embodiment may be manufactured in advance before the semiconductor chip 120 is mounted. The insulating layer 131 of the interposer 130 may include a thermosetting resin such as an epoxy resin, a thermoplastic resin such as a polyimide resin, or a resin in which a reinforcing material such as a glass fiber and/or an inorganic filler is impregnated, for example, prepreg, Ajinomoto Build up Film (ABF), FR-4, Bismaleimide Triazine (BT), or the like. The first wiring patterns 132 and the first vias 133 constituting the first redistribution layer 135 may include a conductive material such as copper (Cu), aluminum (Al), silver (Ag), tin (Sn), gold (Au), nickel (Ni), lead (Pb), or alloys thereof, but are not limited thereto.

The semiconductor chip 120 may be bonded to the interposer 130 through the bonding layer 125 such as an adhesive film, as described above, and be supported by the interposer 130. The interposer 130 may include heat dissipation patterns HD disposed on the inactive surface of the semiconductor chip 120. The heat dissipation patterns HD may be a stack via structure of wiring patterns 132′ and vias 133′, but is not limited thereto. Heat generated from the semiconductor chip 120 may be transferred to electrical connection structures 285 through the heat dissipation patterns HD and be thus effectively dissipated (see FIG. 12). The wiring patterns 132′ and the vias 133′ of the heat dissipation patterns HD may be formed together with the first wiring patterns 132 and the first vias 133 of the first redistribution layer 135.

The connection member 160 may be configured to redistribute the connection electrodes 120P of the semiconductor chip 120. In the present exemplary embodiment, the connection member 160 may redistribute several tens to several hundreds of connection electrodes 120P of the semiconductor chip 120 having various functions together with the second redistribution layer 155 to physically or electrically connect the several tens to several hundreds of connection electrodes 120P to an external apparatus through the electrical connection structures 185. Particularly, in the connection electrodes 120P to which the second redistribution layer 155 is connected, other metal connectors such as conductive bumps are not introduced, and the second redistribution layer 155 may be directly connected to pad electrodes of a bare chip. The connection member 160 may be connected to the connection electrodes 120P of the semiconductor chip 120, and may support the semiconductor chip 120 together with the interposer 130.

The insulating layer 161 of the connection member 160 may be formed of the photosensitive insulating material such as the PID resin. The third redistribution layer 165 may include a conductive material such as copper (Cu), aluminum (Al), silver (Ag), tin (Sn), gold (Au), nickel (Ni), lead (Pb), or alloys thereof.

As described above, the third redistribution layer 165 of the connection member 160 may be electrically connected to the semiconductor chip 120 through the second wiring patterns 152 and the connection vias 153, and the first redistribution layer 135 of the interposer 130 may be electrically connected to the semiconductor chip 120 in a bypass manner through the through-vias 154.

The encapsulant 140 may be configured to protect the semiconductor chip 120. In the present exemplary embodiment, the encapsulant 140 may cover the semiconductor chip 120, and may be formed in a region surrounding the semiconductor chip 120 between the interposer 130 and the connection member 160. The encapsulant 140 used in the present exemplary embodiment may be formed of a photosensitive insulating material. As described above, the vias for the second redistribution layer 155 are formed by a lithography process using a photoresist, and may thus be precisely implemented.

The semiconductor package 100 according to the present exemplary embodiment may further include the first and second passivation layers 171 and 172 disposed, respectively, on the interposer 130 and the connection member 160. The first and second passivation layers 171 and 172 may be configured to protect the interposer 130 and the connection member 160, respectively, from external physical or chemical damage, or the like. A material of each of the first and second passivation layers 171 and 172 is not particularly limited. For example, a solder resist may be used as the material of each of the first and second passivation layers 171 and 172.

The electrical connection structures 185 connected to the third redistribution layer 165 of the connection member 160 may be configured to physically or electrically externally connect the semiconductor package 100. For example, the semiconductor package 100 may be mounted on the mother board of the electronic device through the electrical connection structures 185, as described above.

For example, the electrical connection structures 185 may be formed of a low melting point metal such as copper (Cu), aluminum (Al), silver (Ag), tin (Sn), gold (Au), nickel (Ni), or the like, but is not limited thereto, and the electrical connection structures 185 may have various structures such as lands, balls, pins, and the like.

At least one passive component 190 may be disposed on the second surface 160B of the connection member 160, if necessary, and be connected to the third redistribution layer 165. In the present exemplary embodiment, the passive component 190 may be disposed between the electrical connection structures 185, but is not limited thereto.

As illustrated in FIG. 10B, some of the electrical connection structures 185 may be disposed in a fan-out region. A fan-out package may have excellent reliability as compared to a fan-in package, may implement a plurality of input/output (I/O) terminals, and may facilitate a 3D interconnection. An array (the number, an interval, or the like) of the electrical connection structures 185 is not particularly limited, but may be variously modified depending on a condition of an external apparatus on which the semiconductor package is to be mounted.

In the present exemplary embodiment, a case in which the electrical connection structures 185 are provided on only the second surface 160B of the connection member 160 is illustrated, but connection terminals similar to the electrical connection structures 185 may also be provided on the interposer 130, that is, the pads P, if necessary.

FIG. 12 is a side cross-sectional view illustrating a semiconductor device 300 of a package-on-package (POP) structure including the semiconductor package 100 illustrated in FIG. 9.

Referring to FIG. 12, the semiconductor device 300 according to the present exemplary embodiment may include the semiconductor package 100 provided as a lower package and an upper package 200 disposed on the first surface 130A of the interposer 130.

The upper package 200 may include a connection member 210 provided as a support substrate and having insulating layers 211 and redistribution layers 215 formed on the insulating layers 211, semiconductor chips 220 mounted on the connection member, and an encapsulant 240 formed on the connection member 210 and encapsulating the semiconductor chips 220.

The upper package 200 may be connected to the pads P of the lower package 100 using additional electrical connection structures 285 provided on the first surface 130A of the interposer 130 of the lower package 100 to constitute one module.

A package-on-package (POP) may reduce a thickness of the device, and significantly reduce signal paths. For example, in a case of a graphic processor (GPU), it is required to significantly reduce signal paths between the GPU and a memory such as a high bandwidth memory (HBM). To this end, the upper package 200 and the lower package 100 may be used as a POP structure by stacking the upper package 200 including the semiconductor chip 220 such as the HBM on the lower package 100 in which the semiconductor chip 120 such as the GPU is mounted.

FIGS. 13A through 13F are cross-sectional views illustrating main processes of a method of manufacturing the semiconductor package illustrated in FIG. 9.

Referring to FIG. 13, the interposer 130 having the first and second surfaces 130A and 130B opposing each other and including the first redistribution layer 135 may be provided.

In the present exemplary embodiment, the interposer 130 may serve to connect the upper and lower packages to each other, and may be prepared in advance before the semiconductor chip 120 is mounted (see FIG. 13B). The first redistribution layer 135 implemented in the interposer 130 may include the plurality of first wiring patterns 132 and the plurality of first vias 133 connected to the plurality of first wiring patterns 132. A case in which the first redistribution layer 135 has a two-layer redistribution structure is illustrated by way of example. However, the first redistribution layer 135 is not limited thereto, but may be implemented by a single layer or three or more layers.

As illustrated in FIG. 13A, wiring patterns adjacent to the first surface 130A of the interposer among the plurality of first wiring patterns 132 may protrude from a surface of the insulating layer 131, and wiring patterns adjacent to the second surface 130B of the interposer among the plurality of first wiring patterns 132 may be embedded in the interposer 130, that is, the insulating layer 131. Such a feature may indicate a direction in which the interposer 130 is formed, similar to widths of vias. For example, it may be understood that the interposer 130 is formed from the second surface 130B toward the first surface 130A as opposed to a direction in which the interposer 130 is disposed in FIG. 13A, and it indicates that the interposer 130 used in the present exemplary embodiment is a structure manufactured in advance.

The interposer 130 may include the heat dissipation patterns HD disposed in a region in which the semiconductor chip is to be mounted. The heat dissipation patterns HD may include the wiring patterns 132′ and the vias 133′ formed together with the first wiring patterns 132 and the first vias 133 of the first redistribution layer 135 by the same process as a process of forming the first wiring patterns 132 and the first vias 133.

An area of a surface of the via 133 of the first redistribution layer 135 adjacent to the first surface 130A of the interposer 130 may be smaller than that of a surface of the first via 133 of the first redistribution layer 135 adjacent to the second surface 130B of the interposer 130, but is not limited thereto. That is, a direction of the via may be reversed, if necessary. The first passivation layer 171 may be formed on the first surface 130A of the interposer 130. The first passivation layer 171 may have the first openings O1 defining the plurality of pads P. The first openings O1 may be formed to correspond to an array of connection terminals of another semiconductor chip and package to be disposed on the semiconductor package.

Then, referring to FIG. 13B, the semiconductor chip 120 may be mounted on the second surface 130B of the interposer 130.

The semiconductor chip 120 used in the present exemplary embodiment may have the active surface having a plurality of connection electrodes 120P disposed thereon and the inactive surface opposing the active surface. In the present process, the semiconductor chip 120 may be bonded to the interposer 130 using the bonding layer 125 so that the inactive surface of the semiconductor chip 120 is in contact with the second surface 130B of the interposer 130 manufactured in advance.

Since the interposer 130 includes the heat dissipation patterns HD disposed in a region corresponding to the inactive surface of the semiconductor chip 120, heat generated from the semiconductor chip 120 may be transferred to and dissipated by the electrical connection structures 170 through the heat dissipation patterns HD.

Particularly, a portion of an underfill or the encapsulant 140 is not disposed between the interposer 130 and the semiconductor chip 120, which may contribute to reducing an entire thickness of the semiconductor package, and a distance between the semiconductor chip 120 and the heat dissipation patterns HD may be reduced to ensure effective heat dissipation.

Then, referring to FIG. 13C, the encapsulant 140 may be formed on the second surface 130B of the interposer 130 to encapsulate the semiconductor chip 120.

The encapsulant 140 may be formed of the photosensitive material. In the present exemplary embodiment, the encapsulant 140 may cover the semiconductor chip 120, and may be formed in a region surrounding the semiconductor chip 120 on the interposer 130. The encapsulant 140 may be divided into the first region 140A covering the semiconductor chip 120 and the second region 140B positioned in the vicinity of the semiconductor chip 120.

Then, referring to FIG. 13D, first holes H1 exposing the connection electrodes 120P of the semiconductor chip 120 and second holes H2 exposing partial regions of the first redistribution layer 135 may be formed in the encapsulant 140.

In the present exemplary embodiment, the encapsulant may be formed of the photosensitive material, and a process of forming the holes may thus be precisely performed by a lithography process using a photoresist. The first holes H1 for the connection vias and the second holes H2 for the through-vias may be simultaneously formed in the first region and the second region, respectively.

In the present process, the first holes H1 and the second holes H2 may be drilled from the upper surface of the encapsulant 140, and side cross sections of the first and second holes H1 and H2 may thus tend to become narrow in a downward direction. In the present exemplary embodiment, in the connection electrodes 120P of the semiconductor chip 120, other metal connectors such as conductive bumps are not introduced, and a separate planarization process for exposing the conductive bumps, or the like, may not be required.

Then, referring to FIG. 13E, the second redistribution layer 155 may be formed on the encapsulant 140 so that the first holes H1 and the second holes H2 are filled.

The second redistribution layer 155 may be formed by forming a photoresist layer on the encapsulant 140, forming photoresist patterns by a lithography process, performing a plating process, and then removing the photoresist patterns. The second redistribution layer 155 may include the connection vias 153 penetrating through the first region 140A of the encapsulant 140 and connected to the connection electrodes 120P and the through-vias 154 penetrating through the second region 140B of the encapsulant 140 and connected to the first redistribution layer 135. In addition, the second redistribution layer 155 may include the second wiring patterns 152 disposed on the encapsulant 140 and connected to at least one of the connection vias (or the second vias) 153 and the through-vias 154. The second wiring patterns 152 may be formed together with the connection vias 153 and the through-vias 154. Resultantly, the second wiring patterns 152 may have the integrated structures with the connection vias 153 and the through-vias 154. As described above, the connection vias 153 and the through-vias 154 may be formed of the same metal as that of the second wiring patterns 152.

Then, referring to FIG. 13F, the connection member 160 having the third redistribution layer 165 may be formed on the encapsulant 140.

The third redistribution layer 165 may be connected to the second redistribution layer 155. The third redistribution layer 165 may provide a backside redistribution structure together with the second redistribution layer 155. Each of the insulating layers 161 may be formed of the photosensitive insulating material such as the PID, and the third redistribution layer 165 may be formed by the lithography process using the photoresist.

In detail, the third redistribution layer 165 may include the third wiring patterns 162 and the third vias 163 formed using the two insulating layers 161. Since the third wiring patterns 162 and the third vias 163 related to the respective insulating layers 161 are formed by the same plating process, they may have an integrated structure. The third redistribution layer 165 may include a conductive material such as copper (Cu), aluminum (Al), silver (Ag), tin (Sn), gold (Au), nickel (Ni), lead (Pb), or alloys thereof.

The second passivation layer 172 may be formed on the second surface 160B of the connection member 160 using a material similar to that of the first passivation layer 171, the openings O2 may be formed so that the third redistribution layer 165 is exposed, and the UBM layer 181 may thus be formed.

Then, the electrical connection structures 185 may be formed on the UBM layer 181, and a required passive component 190 may be mounted to manufacture the semiconductor package 100 illustrated in FIG. 9.

In the semiconductor package 100 according to the present exemplary embodiment, the through-vias 154 disposed in the second region 140B of the encapsulant 140 may be provided as vertical connection structures connecting the first and third redistribution layers 135 and 165 to each other. The vertical connection structures may be formed together with the connection vias 153 in a process of forming the connection vias 153 without introducing other structures such as separate conductive bumps, such that a thickness of the semiconductor package may be reduced and the vertical connection structures may be easily formed.

In another exemplary embodiment, some of the vertical connection structures may be replaced by posts connected to the first redistribution layer 135 to reduce a height of the through-vias 154, resulting in a reduction in a deviation of a plating process for forming the connection vias.

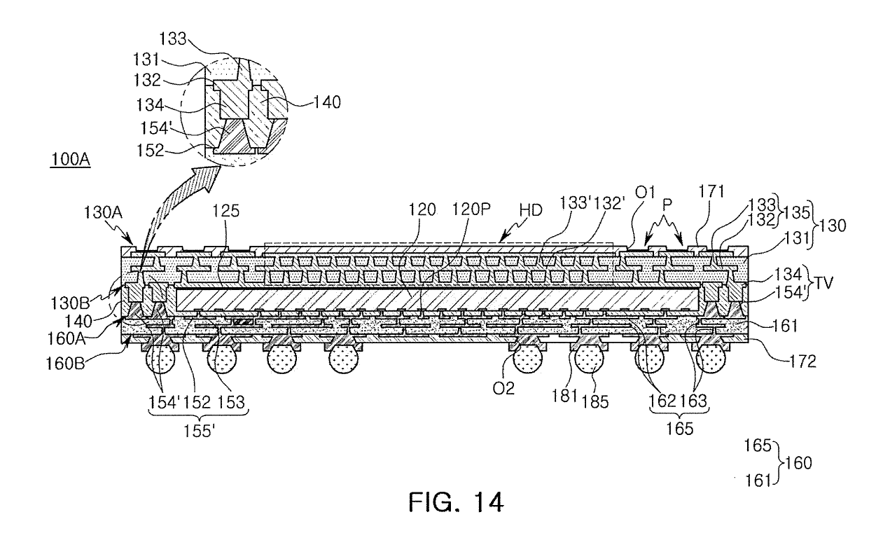

FIG. 14 is a side cross-sectional view illustrating a semiconductor package 100A according to another exemplary embodiment in the present disclosure.

Referring to FIG. 14, it may be understood that the semiconductor package 100A according to the present exemplary embodiment is similar to the semiconductor package 100 illustrated in FIGS. 9 through 11 except that vertical connection structures are implemented by coupled structures between conductive posts and through-vias 154. Components according to the present exemplary embodiments may be understood with reference to the description for the same or similar components of the semiconductor package 100 illustrated in FIGS. 9 through 11 unless explicitly described to the contrary.

An interposer 130 used in the present exemplary embodiment may further include conductive posts 134 disposed on the first redistribution layer 135 in the first region of the encapsulant 140 positioned in the vicinity of the semiconductor chip 120. The conductive posts 134 may be formed on the first wiring patterns 132 exposed on the second surface 130B of the interposer 130, by a plating process. The conductive posts 134 may include, for example, copper (Cu), aluminum (Al), silver (Ag), tin (Sn), gold (Au), nickel (Ni), lead (Pb), or alloys thereof.

Through-vias 154′ of the second redistribution layer 155 may be formed on the conductive posts 134, and may be provided as vertical connection structures TV together with the conductive post 134. An upper surface of the conductive post 134 may be formed at a relatively large area to include a lower surface of the through-via 154′. In the present exemplary embodiment, a height of the through-vias 154′ formed together with the connection vias 153 in a process of plating the connection vias 153 may be reduced to reduce a deviation between plating layers formed in two regions.

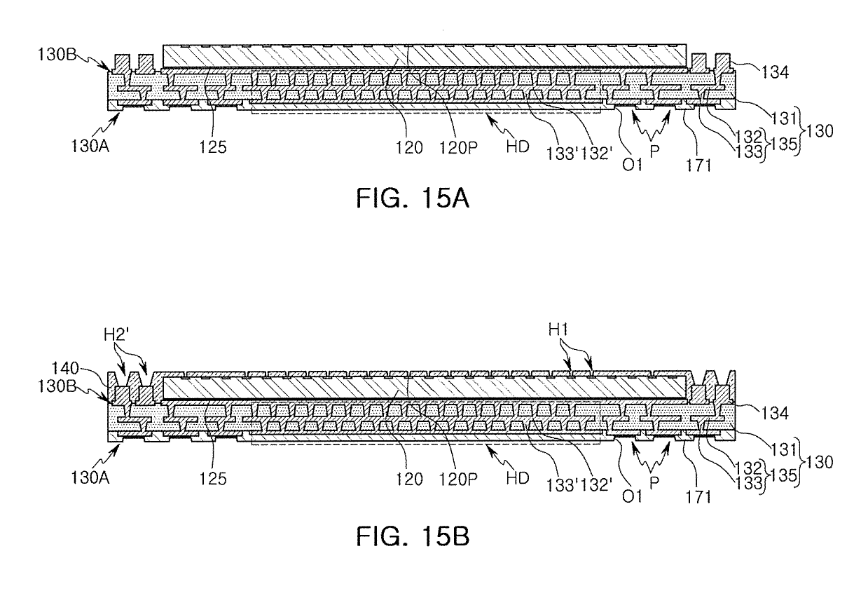

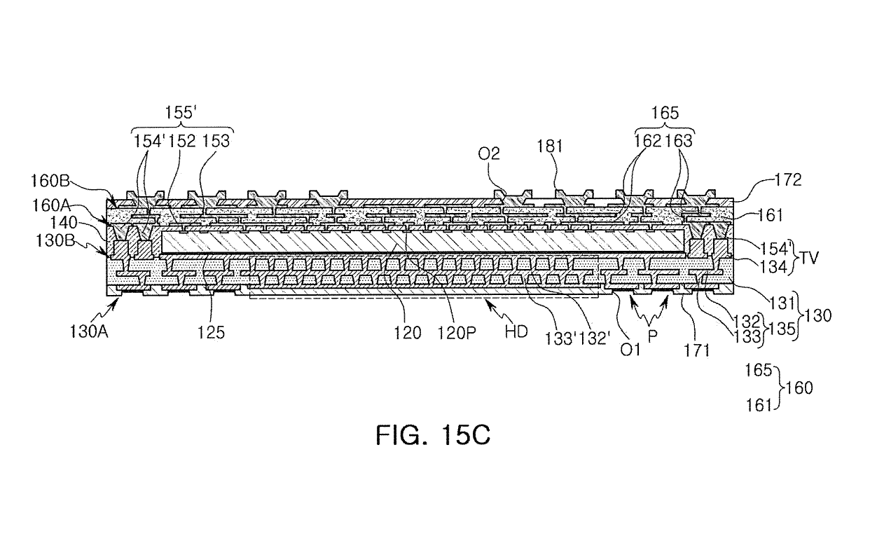

FIGS. 15A through 15C are cross-sectional views illustrating main processes of a method of manufacturing the semiconductor package illustrated in FIG. 14.

Referring to FIG. 15A, the interposer 130 having the first redistribution layer 135 and the conductive posts 134 may be provided.

It may be understood that this process is the same process as a process of providing the interposer 130 illustrated in FIG. 13A except that the interposer 130 has the conductive posts 134. The conductive posts 134 may be formed in the vicinity of a region of the first redistribution layer 135 of the interposer 130 in which the semiconductor chip is to be mounted. The conductive posts 134 may define regions in which the vertical connection structures for connection to a third redistribution layer 165 (see FIG. 15C) to be formed in a subsequent process are to be formed. The conductive posts 134 may have a height corresponding to 30 to 100% of a height at which the semiconductor chip 120 is mounted, but are not limited thereto.

Then, referring to FIG. 15B, the semiconductor chip 120 may be mounted on the second surface 130B of the interposer 130 using the bonding layer 125, and the encapsulant 140 formed of the photosensitive materials may be formed on the second surface 130B of the interposer 130 to encapsulate the semiconductor chip 120. Then, first holes H1 exposing the connection electrodes 120P of the semiconductor chip 120 and second holes H2′ exposing the conductive posts 134 of the first redistribution layer 135 may be formed in the encapsulant 140. These processes may be performed similarly to the processes described in FIGS. 13B through 13E, and the related description may be combined with a description of the present process.

The second holes H2′ obtained in the present process may be formed at a depth smaller than that of the second holes H2 illustrated in FIG. 13D, due to the conductive posts 134 prepared in advance.

Then, referring to FIG. 15C, a second redistribution layer 155′ may be formed on the encapsulant 140 so that the first holes H1 and the second holes H2′ are filled, and the connection member 160 having the third redistribution layer 165 may be formed on the encapsulant 140.

Since a depth deviation between the second holes H2′ formed in the present exemplary embodiment and the first holes H1 is smaller than that between the second holes H2 illustrated in FIG. 13D and the first holes H1, the through-vias 154′ may be formed by a relatively short plating process, and stable vertical connection structures TV for connecting the first and third redistribution layers 135 and 165 to each other may be more easily formed.

The third redistribution layer 165 may be connected to the second redistribution layer 155′. The third redistribution layer 165 may provide a backside redistribution structure together with the second redistribution layer 155′ (see FIG. 13F).

Then, the electrical connection structures 185 may be formed on the UBM layer 181 to manufacture the semiconductor package 100A illustrated in FIG. 14.

As set forth above, according to the exemplary embodiments in the present disclosure, a connection structure and a process may be simplified and a heat dissipation path for the semiconductor chip may be effectively improved, by utilizing the connection member manufactured in advance as the interposer. In addition, the vertical connection structures of the redistribution layers may be manufactured together with a redistribution structure for the semiconductor chip by introducing the photosensitive material as a material of the encapsulant.

While exemplary embodiments have been shown and described above, it will be apparent to those skilled in the art that modifications and variations could be made without departing from the scope of the present invention as defined by the appended claims.

What is claimed is:

1. A semiconductor package comprising:
an interposer having a first surface and a second surface opposing each other and including a first redistribution layer having a plurality of first wiring patterns and first vias connected to the plurality of first wiring patterns;
a semiconductor chip having an active surface having connection electrodes disposed thereon and an inactive surface opposing the active surface and disposed on the interposer so that the inactive surface faces the second surface of the interposer;
an encapsulant disposed on the second surface of the interposer, including a photosensitive insulating material, and having a first region covering the active surface of the semiconductor chip and a second region positioned in the vicinity of the semiconductor chip; and
a second redistribution layer including second vias penetrating through the first region of the encapsulant and connected to the connection electrodes, through-vias penetrating through the second region of the encapsulant and connected to the first redistribution layer, and second wiring patterns disposed on the encapsulant and having integrated structures with the second vias and the through-vias.

2. The semiconductor package of claim 1, further comprising a connection member having a first surface disposed on the encapsulant and a second surface opposing the first surface, the connection member including a third redistribution layer connected to the second redistribution layer.

3. The semiconductor package of claim 2, wherein the third redistribution layer includes a plurality of third wiring patterns and a plurality of third vias connected to the plurality of third wiring patterns, and
the plurality of third vias have a width that is reduced toward the first surface of the connection member.

4. The semiconductor package of claim 1, wherein the first vias have a width that is reduced toward the first surface of the interposer.

5. The semiconductor package of claim 1, wherein first wiring patterns adjacent to the first surface of the interposer among the plurality of first wiring patterns protrude from the interposer, and first wiring patterns adjacent to the second surface of the interposer among the plurality of first wiring patterns are embedded in the interposer.

6. The semiconductor package of claim 1, wherein the second vias and the through-vias are formed of substantially the same metal.

7. The semiconductor package of claim 1, wherein an area of a surface of the second vias adjacent to the semiconductor chip is smaller than that of a surface of the second vias adjacent to the connection member.

8. The semiconductor package of claim 1, wherein an area of a surface of the through-vias adjacent to the interposer is smaller than that of a surface of the through-vias adjacent to the connection member.

9. The semiconductor package of claim 1, further comprising a bonding layer disposed between the inactive surface of the semiconductor chip and the second surface of the interposer.

10. The semiconductor package of claim 1, wherein the interposer further includes heat dissipation patterns disposed in a region corresponding to the semiconductor chip.

11. The semiconductor package of claim 10, wherein the heat dissipation patterns include a stack structure of a plurality of wiring patterns and vias.

12. The semiconductor package of claim 1, wherein the interposer further includes conductive posts disposed on lower surfaces of the through-vias and connected to the first redistribution layer, and
the through-vias are disposed on the conductive posts and are electrically connected to the first redistribution layer through the conductive posts.

13. The semiconductor package of claim 12, wherein surfaces of the conductive posts, meeting the lower surfaces of the through-vias, have a relatively large area than the lower surfaces of the through-vias.

14. The semiconductor package of claim 12, wherein the conductive posts have a height corresponding to 30 to 100% of a height at which the semiconductor chip is mounted.

15. The semiconductor package of claim 2, further comprising electrical connection structures disposed on the second surface of the connection member and connected to the third redistribution layer.

16. The semiconductor package of claim 15, further comprising a passivation layer disposed on at least one of the second surface of the connection member and the first surface of the interposer.

17. The semiconductor package of claim 15, further comprising an underbump metallurgy (UBM) layer disposed on the second surface of the connection member and connecting the third redistribution layer and the electrical connection structures to each other.

18. The semiconductor package of claim 1, further comprising a plurality of pads disposed on the first surface of the interposer and connected to the first redistribution layer.

19. A semiconductor package comprising:
an interposer having a first surface having a plurality of pads provided thereon and a second surface opposing the first surface and including a first redistribution layer connected to the plurality of pads;
a semiconductor chip having an active surface having connection electrodes disposed thereon and an inactive surface opposing the active surface and disposed on the interposer so that the inactive surface faces the second surface of the interposer;
an encapsulant disposed on the second surface of the interposer, including a photosensitive insulating material, and having a first region covering the active surface of the semiconductor chip and a second region positioned in the vicinity of the semiconductor chip;
a second redistribution layer including connection vias penetrating through the first region of the encapsulant and connected to the connection electrodes, through-vias penetrating through the second region of the encapsulant and connected to the first redistribution layer, and wiring patterns disposed on the encapsulant and having integrated structures with the connection vias and the through-vias; and
a connection member having a first surface disposed on the encapsulant and a second surface opposing the first surface and having electrical connection structures disposed thereon, and including a third redistribution layer connected to the second redistribution layer and the electrical connection structures,
wherein the first redistribution layer has a plurality of first wiring patterns and first vias connected to the plurality of first wiring patterns, first wiring patterns adjacent to the first surface of the interposer among the plurality of first wiring patterns protrude from the interposer, and first wiring patterns adjacent to the second surface of the interposer among the plurality of first wiring patterns are embedded in the interposer.
